(19) United States
(12) Patent Application Publication
(10) Pub. No.: US 2023/0020028 A1
(43) Pub. Date: Jan. 19, 2023

(54) LED-MOUNTED SUBSTRATE, AND SURFACE LIGHT-EMITTING BODY AND VIDEO DISPLAY DEVICE USING SAME

(71) Applicant: Mitsubishi Electric Corporation, Tokyo (JP)

(72) Inventors: Yohei ITO, Tokyo (JP); Sohei SAMEJIMA, Tokyo (JP); Satoru KIRIDOSHI, Tokyo (JP)

(73) Assignee: Mitsubishi Electric Corporation, Tokyo (JP)

(21) Appl. No.: 17/786,540

(22) PCT Filed: Jan. 9, 2020
(86) PCT No.: PCT/JP2020/000454

§ 371 Date: Jun. 17, 2022

(51) Int. Cl. H01L 25/16; H01L 33/62

(52) U.S. Cl. CPC H01L 25/162; H01L 25/167; H01L 33/62

(57) ABSTRACT

An LED board includes a flexible printed circuit and multiple LED-mounted parts arrayed on the circuit board at regular intervals in a constant direction. The LED-mounted parts each include multiple LEDs. The circuit board includes LED portions including the LED-mounted parts and non-LED portions including no LED-mounted parts that are arrayed alternately. The LED-mounted parts each have, in an array direction in which the LED-mounted parts are arrayed, a dimension equal to an interval between adjacent LED-mounted parts of the arrayed LED-mounted parts. A surface emitter includes multiple LED boards fitted together, with LED-mounted parts on each LED board overlapping non-LED portions of an adjacent LED board of the LED boards. The LED board and the surface emitter with the above structures easily upsize a video display device.

### TECHNICAL FIELD

The present disclosure relates to a light-emitting diode (LED) board including multiple LEDs mounted on a printed circuit board, and a surface emitter and a video display device including such LED boards.

### BACKGROUND ART

Known video display devices typically include surface emitters each including multiple LEDs mounted on a flat, rigid, and plate-shaped printed circuit board accommodated in a resin case. Such surface emitters are connected together or fastened to a housing to be a video display device. With the flat, rigid, and plate-shaped printed circuit board unbendable, the video display device is to be installed at limited places with a flat surface or a large curvature.

Patent Literature 1 describes a surface emitter that includes a flexible printed circuit board including electric wiring, multiple LEDs substantially regularly arranged on the board, and a top film stretching over the surfaces of the LEDs.

### CITATION LIST

### Patent Literature

Patent Literature 1: Unexamined Japanese Patent Application Publication No. 2011-215641

### SUMMARY OF INVENTION

### Technical Problem

The surface emitter described in Patent Literature 1 includes a flexible board. To upsize a video display device and to increase the length and width of the video display device, connectors for connecting the surface emitters to one another is to be separately prepared. An objective of the present disclosure is to provide an LED board for easily upsizing a video display device, and a surface emitter and a video display device including such LED boards.

### Solution to Problem

An LED board according to an aspect of the present disclosure includes a circuit board being flexible, and a plurality of LED-mounted parts arrayed on the circuit board at regular intervals in a constant direction. Each of the plurality of LED-mounted parts includes a plurality of LEDs being light-emitting diodes. The circuit board includes LED portions including the plurality of LED-mounted parts and non-LED portions including no LED-mounted parts. The LED portions and the non-LED portions are arrayed alternately. The plurality of LED-mounted parts each have, in an array direction in which the plurality of LED-mounted parts are arrayed, a dimension equal to an interval between adjacent LED-mounted parts of the arrayed plurality of LED-mounted parts. A surface emitter according to another aspect of the present disclosure includes a plurality of the LED boards fitted together, with the plurality of LED-mounted parts on each of the plurality of LED boards overlapping the non-LED portions of an adjacent LED board of the plurality of LED boards.

### Advantageous Effects of Invention

The LED board and the surface emitter with the structures according to the above aspects of the present disclosure easily upsize a video display device.

### BRIEF DESCRIPTION OF DRAWINGS

FIG. 1 is a schematic plan view of an LED board included in a surface emitter in a video display device according to Embodiment 1;

FIG. 2 is a partially enlarged perspective view of the surface emitter in the video display device according to Embodiment 1, illustrating a video display surface of the surface emitter;

FIG. 3 is a schematic plan view of the LED board included in the surface emitter in the video display device according to Embodiment 1, including component mounts;

FIG. 4 is a schematic plan view of the LED board included in the surface emitter in the video display device according to Embodiment 1, including component mounts;

FIG. 5 is a schematic plan view of an LED board included in a surface emitter in a video display device according to Embodiment 2;

FIG. 6 is a schematic plan view of an LED board included in a surface emitter in a video display device according to Embodiment 3;

FIG. 7 is a schematic plan view of a surface emitter in a video display device according to Embodiment 4, illustrating the back of a video display surface of a surface emitter;

FIG. 8 is a schematic plan view of the surface emitter in the video display device according to Embodiment 4, illustrating the video display surface;

FIG. 9 is a perspective view of the surface emitter in the video display device according to Embodiment 4, illustrating the video display surface;

FIG. 10 is a schematic plan view of two fitted LED boards each including the LED boards included in the surface emitter in the video display device according to Embodiment 4 fitted together;

FIG. 11 is a schematic plan view of the surface emitter including the two fitted LED boards according to Embodiment 4 overlapping each other;

FIG. 12 is a plan view of the surface emitter in the video display device according to Embodiment 4 without staggered ends in a vertical direction;

FIG. 13 is a schematic plan view of the surface emitter in the video display device according to Embodiment 4 without staggered ends in the vertical direction;

FIG. 14 is a partial cross-sectional view of the LED boards included in the surface emitter in the video display device according to Embodiment 4, illustrating the video display surfaces of the LED boards;

FIG. 15 is a partial cross-sectional view of a LED board included in the surface emitter in the video display device according to Embodiment 4, illustrating the back of the video display surface of the LED board;

FIG. 16 is a partial cross-sectional view of a LED board included in the surface emitter in the video display device according to Embodiment 4, illustrating the back of the video display surface of the LED board;

FIG. 17 is a schematic cross-sectional view of the surface emitter in the video display device according to Embodiment 4, with the video display surface of the surface emitter coated with resin;

FIG. 18 is a schematic cross-sectional view of the surface emitter in the video display device according to Embodiment 4, with a light shield located on the back of the video display surface;

FIG. 19 is a schematic cross-sectional view of the surface emitter in the video display device according to Embodiment 4, with connection parts bonded to LED-mounted parts on the LED board included in the surface emitter;

FIG. 20 is a schematic plan view of a surface emitter in a video display device according to Embodiment 5, illustrating the back of a video display surface of a surface emitter;

FIG. 21 is a schematic plan view of the surface emitter in the video display device according to Embodiment 5, illustrating the video display surface;

FIG. 22 is a perspective view of the surface emitter in the video display device according to Embodiment 5, illustrating the video display surface;

FIG. 23 is a schematic plan view of two LED boards included in the surface emitter in the video display device according to Embodiment 5;

FIG. 24 is a schematic plan view of two fitted LED boards each including the LED boards included in the surface emitter in the video display device according to Embodiment 5;

FIG. 25 is a schematic plan view of the surface emitter including the two fitted LED boards according to Embodiment 5 overlapping each other;

FIG. 26 is a partial cross-sectional view of the LED boards included in the surface emitter in the video display device according to Embodiment 5, illustrating the video display surfaces of the LED boards;

FIG. 27 is a partial cross-sectional view of the LED boards included in the surface emitter in the video display device according to Embodiment 5, illustrating the back of the video display surfaces;

FIG. 28 is a schematic plan view of a surface emitter in a video display device according to Embodiment 6, illustrating the back of a video display surface of the surface emitter;

FIG. 29 is a schematic plan view of the surface emitter in the video display device according to Embodiment 6, illustrating the video display surface;

FIG. 30 is a perspective view of the surface emitter in the video display device according to Embodiment 6, illustrating the video display surface;

FIG. 31 is a view of LED boards arrayed in an array direction included in the video display device according to Embodiment 6;

FIG. 32 is a view of LED boards arrayed in a vertical direction included in the video display device according to Embodiment 6;

FIGS. 33A and 33B are plan and side views of a video display device according to Embodiment 7; and

FIG. 34 is a structural diagram of the video display device according to Embodiment 7, illustrating a use example of the video display device.

### DESCRIPTION OF EMBODIMENTS

### Embodiment 1

An LED board according to Embodiment 1 includes a flexible printed circuit, and LED-mounted parts each including multiple LEDs and arrayed on the circuit board at regular intervals in a specific direction. The circuit board includes LED portions including the LED-mounted parts and non-LED portions including no LED-mounted parts. The LED portions and the non-LED portions are arrayed alternately. The LED-mounted parts each have a dimension in an array direction in which the LED boards are arrayed. The dimension is equal to an interval between adjacent LED-mounted parts of the arrayed LED-mounted parts. Embodiments of the present disclosure are described below with reference to the drawings. The same or corresponding components are given the same reference numerals throughout the drawings and are not described. The disclosure may be implemented in any form other than in these embodiments.

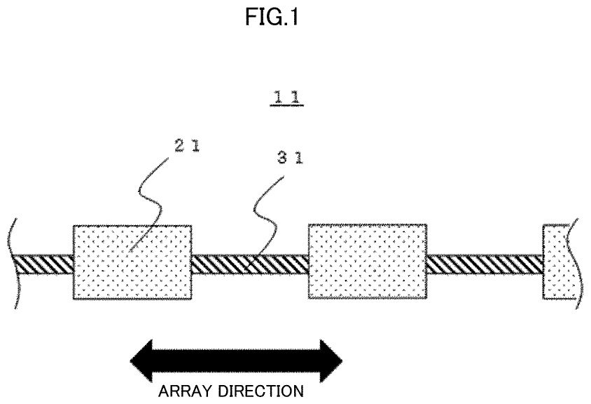

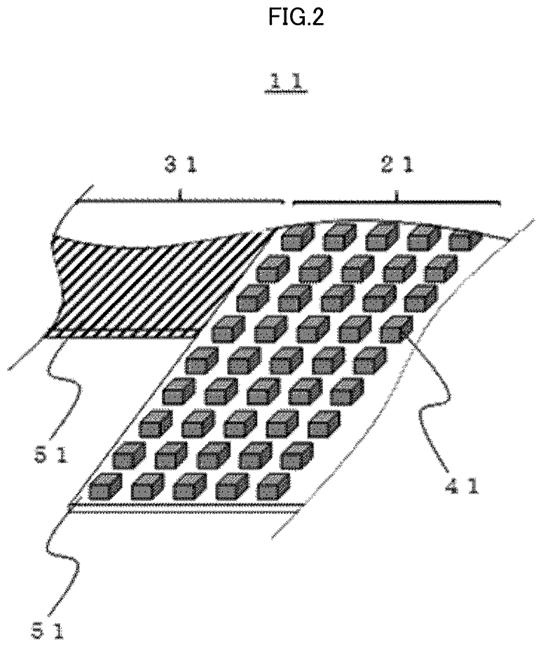

FIG. 1 is a schematic diagram of an LED board included in a surface emitter in a video display device according to Embodiment 1. The LED board according to Embodiment 1 includes a flexible printed circuit, and LED-mounted parts each including multiple LEDs and arrayed on the circuit board at regular intervals in a specific direction. The circuit board includes LED portions including the LED-mounted parts and non-LED portions including no LED-mounted parts. The LED portions and the non-LED portions are arrayed alternately. The LED-mounted parts each have a dimension in an array direction in which the LED boards are arrayed. The dimension is equal to an interval between adjacent LED-mounted parts of the arrayed LED-mounted parts. As illustrated in FIG. 1, an LED board 11 includes multiple LED-mounted parts 21 each including multiple LEDs mounted on a flexible printed circuit (labeled 51 in FIG. 2, described later) and connection parts 31 being portions of the flexible printed circuit each connecting adjacent ones of the LED-mounted parts to each other. Non-LED portions of the circuit board each between adjacent LED-mounted parts are hereafter referred to as connection parts. The LED board 11 includes the LED-mounted parts 21 and the connection parts 31 arrayed at regular intervals in a specific direction. The direction in which the LED-mounted parts and the connection parts are arrayed is defined as an array direction, and the direction perpendicular to the array direction is defined as a vertical direction. Each of the arrayed LED-mounted parts 21 has a boundary with the corresponding connection part 31 in a middle portion of a side of the LED-mounted part 21 in the direction perpendicular to the array direction. Each LED-mounted part 21 has a dimension in the array direction equal to the interval between adjacent LED-mounted parts of the arrayed LED-mounted parts, or more specifically, equal to the dimension of each connection part 31 in the array direction. Such elongated LED boards according to the embodiment of the present disclosure are connected together to have a surface emitter, with the mounts and the connection parts in adjacent LED boards overlapping and fitted to each other. The surface emitter used as a video display device is easily upsized. The surface emitter including the LED boards with the mounts and the connection parts in adjacent LED boards overlapping and fitted to each other is described in detail in and after Embodiment 4.

FIG. 2 is a partially enlarged perspective view of the LED board of the surface emitter in the video display device according to Embodiment 1, illustrating the video display surface of the surface emitter. FIG. 2 shows a portion around the boundary between an LED-mounted part 21 and a connection part 31 in the LED board 11 in an enlarged manner. The LED board 11 includes the LED-mounted parts 21 and the connection parts 31. The LED-mounted parts 21 and the connection parts 31 are portions of the flexible printed circuit 51 including electric wiring. The LED board 11 includes substantially regularly arranged multiple LEDs 41 mounted on the video display surfaces of the LED-mounted parts 21. The LED board 11 also includes an LED control component, which is not illustrated, such as an LED driver integrated circuit (IC) mounted on the board. The LED control component is mounted on the back of the LED-mounted parts 21 or the connection parts 31 in the LED board 11.

A printed circuit board (circuit board 51) included in the LED-mounted parts 21 and the connection parts 31 in the LED board 11 is formed from a film- or sheet-shaped base material. The base material may be selected from various flexible and sturdy materials. Any base material easily processible into a film or sheet and having insulating properties and flexibility is usable. For easy handling and processability, plastics may be used. The base material is selectable from, for example, polyimide, polyethylene terephthalate, polyester, polyvinyl chloride, liquid crystalline polymer, and epoxy resin.

To allow the LEDs 41 to be turned on, the circuit board 51 included in the LED board 11 includes electric wiring to supply signals or power to the LEDs 41 or the LED control component. The electric wiring may be formed in any method including, for example, etching a laminate of a base material and metal foil, depositing metal by plating, and printing with electrically conductive paste. The surface of the circuit board 51 in the LED board 11 may be covered with a solder resist or a cover film for insulation. To improve the contrast performance of the video display device, the portions of the LED boards surrounding the LEDs may be black. For example, the solder resist or the cover film that protects the surface of the circuit board 51 in the LED board 11 may be black.

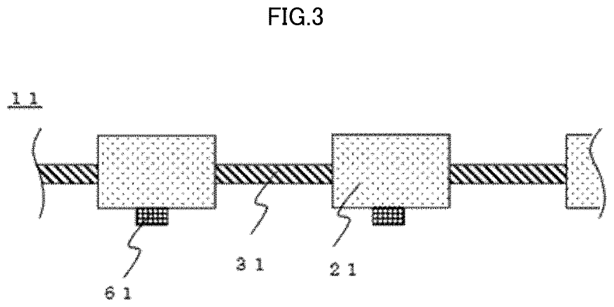

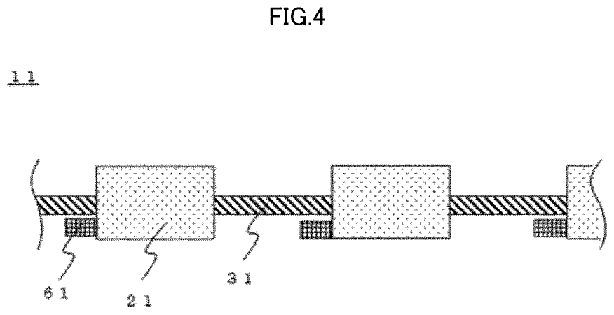

An LED-mounted part on which an LED control component is mounted may be separately provided on a side of each LED-mounted part 21. FIGS. 3 and 4 each are a schematic diagram of the LED board included in the surface emitter in the video display device, including a component mount on each LED-mounted part. As illustrated in FIG. 3, a component mount 61 on which an LED control component is mounted may be separately located on a side of each LED-mounted part 21. In another example, as illustrated in FIG. 4, a component mount 61 on which an LED control component is mounted may be separately located on an extended part of a side of each LED-mounted part 21 at the boundary between the LED-mounted part 21 and the corresponding connection part 31. When the multiple LED boards are fitted, these component mounts 61 are located on the back of the video display surface of the LED-mounted part in the surface emitter.

Such elongated LED boards according to the embodiment of the present disclosure are connected together to have a surface emitter, with the mounts and the connection parts in adjacent LED boards overlapping and fitted to each other. The surface emitter used as a video display device is easily upsized.

### Embodiment 2

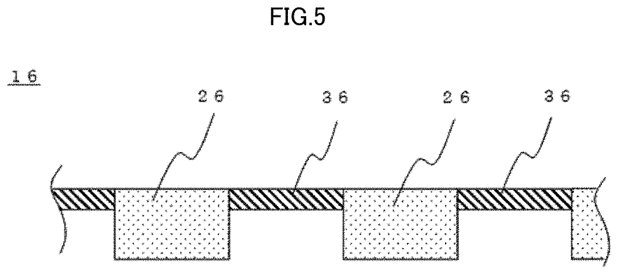

The LED board according to Embodiment 1 includes the flexible printed circuit, and the LED-mounted parts each including multiple LEDs and arrayed on the circuit board at regular intervals in a specific direction. The circuit board includes the LED portions including the LED-mounted parts and the non-LED portions including no LED-mounted parts. The LED portions and the non-LED portions are arrayed alternately. The LED-mounted parts each have a dimension in the array direction equal to the interval between adjacent LED-mounted parts of the arrayed LED-mounted parts. Each of the arrayed LED-mounted parts has a boundary with a corresponding portion of the non-LED portions of the circuit board in a middle portion of the side of the LED-mounted part in the direction perpendicular to the array direction. In an LED board according to Embodiment 2, each of the LED-mounted parts has an edge including a side, the side being parallel to the array direction overlapping an edge of the circuit board on which the LED-mounted parts are provided. FIG. 5 is a schematic plan view of an LED board included in a surface emitter in a video display device according to Embodiment 2. An LED board 16 includes LED-mounted parts 26 and connection parts 36 alternately arranged, with one side of each LED-mounted part 26 and one side of each connection part 36 aligned on a straight line, or more specifically, with one side included in the edge of each LED-mounted part 26 parallel to the array direction of the LED-mounted parts overlapping the edge of the circuit board including the LED-mounted part. The sides of the alternately arranged LED-mounted parts 26 and the connection parts 36 arranged in a straight line have the same length. Such elongated LED boards according to the embodiment of the present disclosure are connected together to have a surface emitter, with the mounts and the connection parts in adjacent LED boards overlapping and fitted to each other. The surface emitter used as a video display device is easily upsized. A video display device including the surface emitters including the LED boards is conveniently installed at, particularly, a place elongated in the array direction of LED boards.

### Embodiment 3

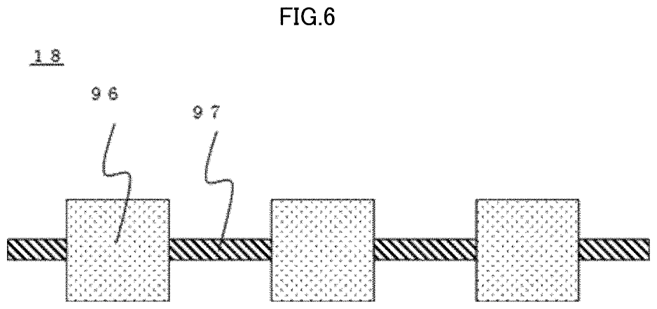

FIG. 6 shows an LED board including square LED-mounted parts and connection parts with a length equivalent to the length of one side of each LED-mounted part. FIG. 6 is a schematic plan view of the LED board included in a surface emitter in a video display device. As illustrated in FIG. 6, an LED board included in a surface emitter according to Embodiment 3 includes a flexible LED board 18 including multiple LED-mounted parts 96 on which multiple LEDs are mounted and connection parts 97 each connecting adjacent ones of the LED-mounted parts to each other. Each connection part 97 is located near a middle portion of the corresponding LED-mounted part 96. Each LED-mounted part 96 is square. The connection parts 97 each have a length equivalent to the length of one side of the LED-mounted parts 96. Being square herein refers to each LED-mounted part 96 having a square profile as viewed in plan. Such elongated LED boards according to the embodiment of the present disclosure are connected together to have a surface emitter, with the mounts and the connection parts in adjacent LED boards overlapping and fitted to each other. The surface emitter used as a video display device is easily upsized. The multiple LED boards according to this embodiment can overlap and be fitted in a knitted manner. A video display device including surface emitters including the LED boards thus has increased strength.

### Embodiment 4

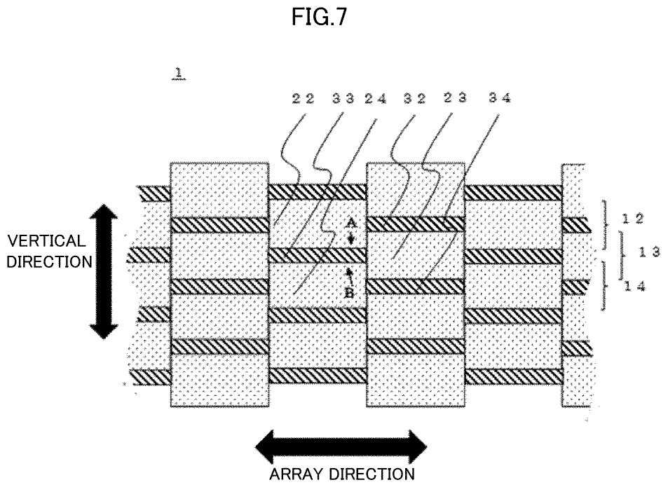

A surface emitter according to Embodiment 4 includes the LED boards according to Embodiment 1 arranged in a direction perpendicular to the array direction of the LED-mounted parts. The LED boards are fitted together, with the LED-mounted part in each LED board and a non-LED portion of an adjacent LED board overlapping and fitted to each other. More specifically, the LED-mounted part of one of adjacent LED boards according to Embodiment 1 and the connection part of the other one of the adjacent LED boards overlap and are fitted to each other. FIG. 7 is a schematic plan view of a surface emitter 1 in a video display device according to Embodiment 4, illustrating the back of the video display surface of the surface emitter 1. In the LED boards included in the surface emitter 1 illustrated in FIG. 7, each of the connection parts is located near a middle portion of the corresponding LED-mounted part. The surface emitter includes LED boards fitted together, with the LED-mounted parts and the connection parts of adjacent LED boards overlapping and fitted to each other. Three adjacent LED boards on the back of the video display surface of the surface emitter 1 in the video display device illustrated in FIG. 7 are referred to as LED boards 12, 13, and 14. The LED board 12 includes LED-mounted parts 22 and connection parts 32. The LED board 13 includes LED-mounted parts 23 and connection parts 33. The LED board 14 includes LED-mounted parts 24 and connection parts 34.

The LED-mounted part 22 on the LED board 12 has a side (indicated with bold arrow A in FIG. 7) overlapping and fitted to the connection part 33 in the LED board 13, and the LED-mounted part 24 on the LED board 14 has a side (indicated with bold arrow B in FIG. 7) overlapping and fitted to the connection part 33 in the LED board 13. The side of the LED-mounted part 22 on the LED board 12 and the side of the LED-mounted part 24 on the LED board 14 are fitted to the connection part 33, with the back of the video display surface of the LED-mounted part 22 on the LED board 12 and the back of the video display surface of the LED-mounted part 24 on the LED board 14 overlapping and fitted to each other while being in contact with the connection part 33 in the LED board 13. On the video display surface, the LED-mounted part 22 on the LED board 12 and the LED-mounted part 24 on the LED board 14 have the respective sides in contact with each other. On the back of the video display surface, the LED-mounted part 23 on the LED board 13 has sides overlapping and fitted to the connection part 32 in the LED board 12 and the connection part 34 in the LED board 14. On the back of the video display surface of the LED-mounted part 23 on the LED board 13, the LED-mounted part 23 on the LED board 13 has sides overlapping and fitted to the mount 22 on the LED board 12 and the connection part 34 in the LED board 14. Although the three adjacent LED boards or the LED boards 12, 13, and 14 have been described, other LED printed circuit boards may be similarly fitted together into the surface emitter in the video display device according to Embodiment 4.

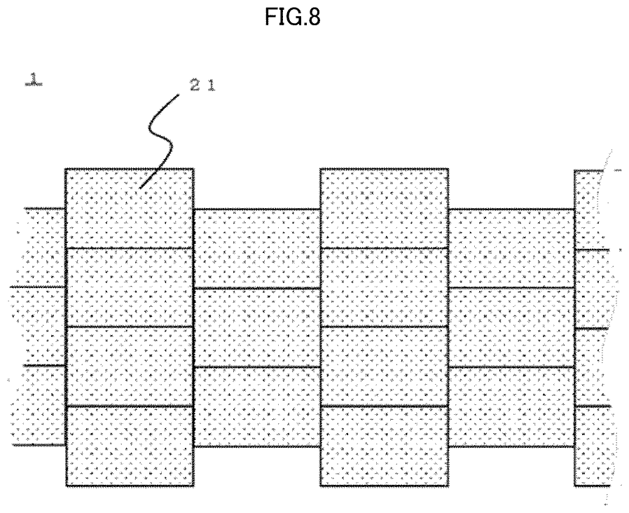

FIG. 8 is a schematic plan view of the surface emitter in the video display device according to Embodiment 4, illustrating the video display surface of the surface emitter. As illustrated in FIG. 8, on the video display surface of the surface emitter 1 in the video display device, the multiple LED-mounted parts 21 on which multiple LEDs are mounted are arrayed at regular intervals. The mounts and the connection parts of adjacent LED boards overlap and are fitted to each other. Thus, the LED-mounted parts 21 on the LED board 11 on which the LEDs are mounted are staggered on the video display surface of the surface emitter 1. The sides of the alternately arrayed LED-mounted parts 21 and connection parts 31 have substantially the same length.

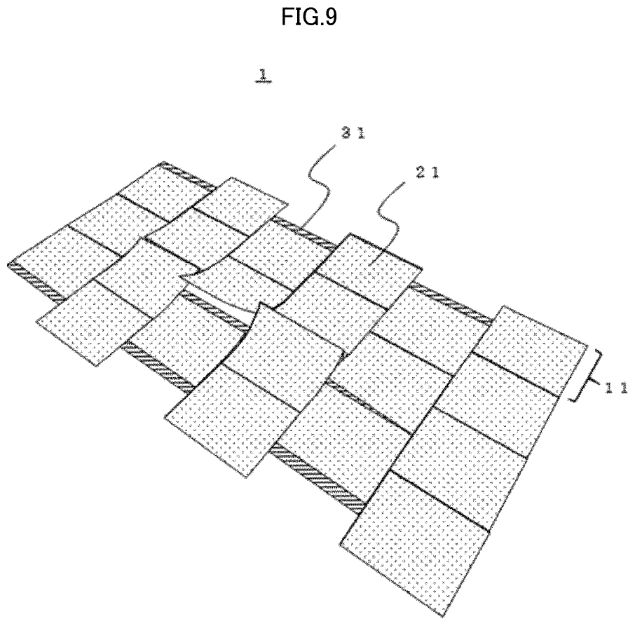

FIG. 9 is a partial perspective view of the surface emitter 1 in the video display device according to Embodiment 4, illustrating the video display surface of the surface emitter 1. In FIG. 9, the LED board 11 includes multiple LED-mounted parts 21 on which multiple LEDs are mounted and connection parts 31 each connecting adjacent LED-mounted parts 21 of the multiple LED-mounted parts 21 to each other. The LED board 11 is flexible. Being flexible refers to, as described above, the circuit board 51 being formed from a film- or sheet-shaped base material. The base material of the circuit board may include base material selected from various flexible and sturdy materials. On the video display surface of the surface emitter 1, the multiple LED-mounted parts 21 on which multiple LEDs are mounted are arrayed at regular intervals. The multiple LED boards overlap and are fitted together to have the surface emitter such that the connection parts in each LED board adjoining are placed on the back of a side of the LED-mounted part of an adjacent LED board. Such elongated LED boards according to the embodiment of the present disclosure are connected together to have a surface emitter, with the mounts and the connection parts in adjacent LED boards overlapping and fitted to each other. The surface emitter used as a video display device is easily upsized.

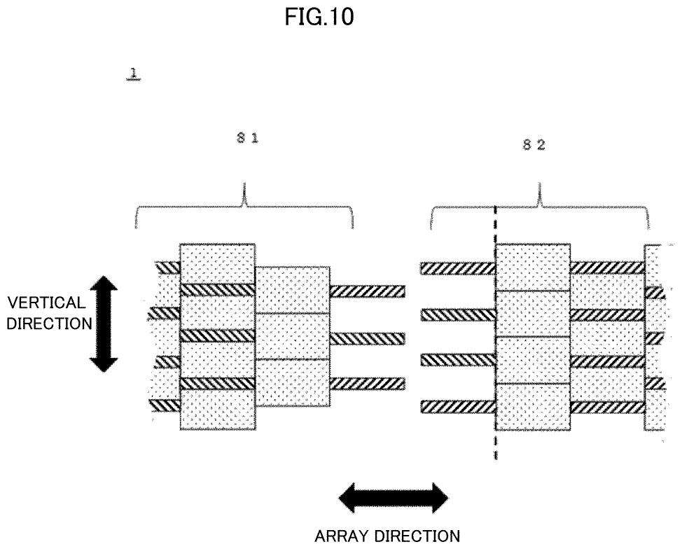

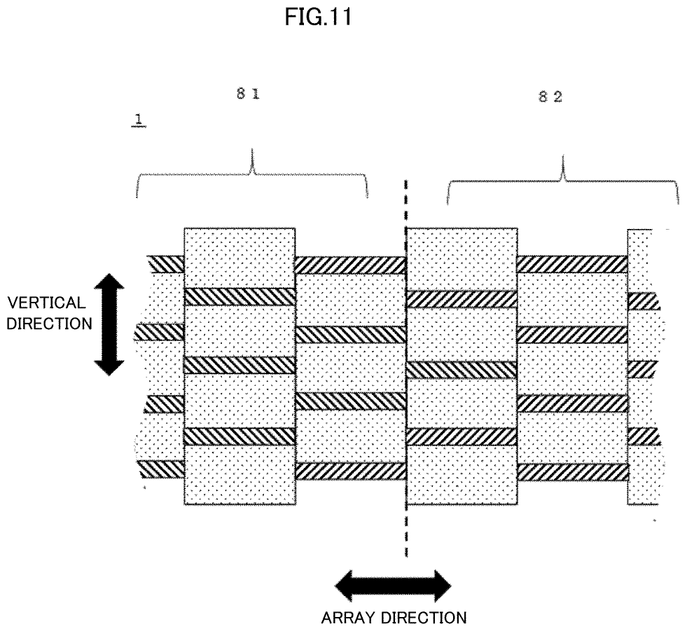

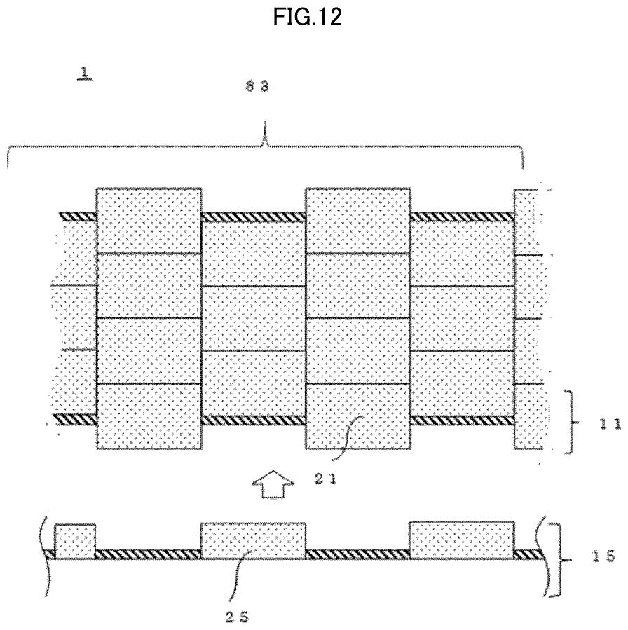

FIG. 10 is a schematic view of two fitted LED boards each including overlapping LED boards included in the surface emitter in the video display device according to Embodiment 4. FIG. 11 is a schematic view of the surface emitter including the two fitted LED boards overlapping each other. As illustrated in FIG. 11, a first fitted LED board 81 including multiple LED boards overlapping vertically and a second fitted LED board 82 including multiple LED boards similarly overlapping vertically overlap each other in the array direction included in the surface emitter in the video display device. The surface emitter is upsized in the vertical and array directions. As illustrated in FIG. 10, the surface emitter illustrated in FIG. 12 has connection parts protruding at one end of the first fitted LED board 81 and connection parts protruding at one end of a second fitted LED board 82 to face the first fitted LED board 81. The connection parts in the second fitted LED board 82 are placed on the back of the LED-mounted parts on the first fitted LED board 81. The connection parts in the first fitted LED board 81 are placed on the back of the LED-mounted parts on the second fitted LED board 82. The first and second fitted LED boards 81 and 82 overlap each other into the surface emitter in the video display device illustrated in FIG. 11 upsized in the array direction.

A larger video display device has a greater overall weight. A large screen with multiple units of fitted LED printed circuit boards as above satisfies both the portability and the installability. The video display device according to embodiments of the present disclosure is flexible, and thus can be folded, rolled, or stored into a compact container for transportation. Dividing a video display device into multiple units of fitted LED printed circuit boards can downsize the storage space and improve the portability.

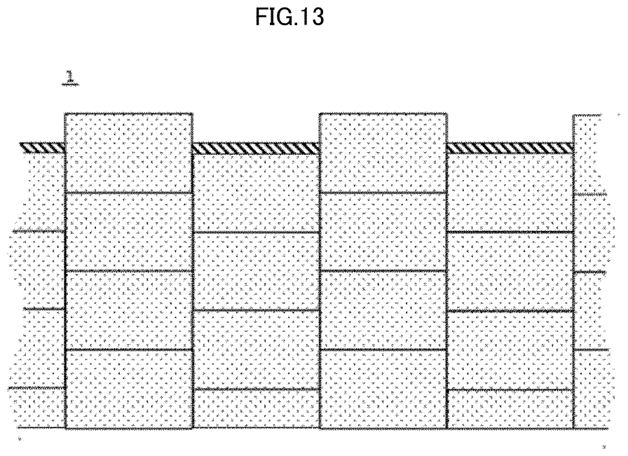

FIG. 12 is a plan view of the surface emitter in the video display device according to Embodiment 1 without staggered ends in the vertical direction. FIG. 13 is a schematic plan view of the surface emitter in the video display device according to Embodiment 4 without staggered ends in the vertical direction. As illustrated in FIG. 12, LED-mounted parts 42 on an LED board 41 having a width half the width of each LED-mounted part 21 on the LED board 11 are fitted to a fitted LED board 83 including the first and second fitted LED boards 81 and 82 fitted together to eliminate the staggered ends in the vertical direction. Another staggered end of the surface emitter in the vertical direction can be also eliminated in this manner. Thus, as illustrated in FIG. 13, the surface emitter in the video display device can eliminate staggered ends in the vertical direction.

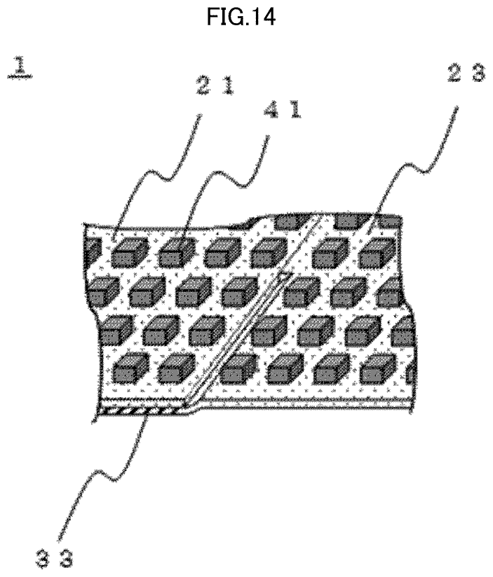

FIG. 14 is a partial cross-sectional view of the LED boards included in the surface emitter in the video display device according to Embodiment 4. The cross section includes the connection parts. The LED-mounted part 21 on which multiple LEDs 41 are mounted is fitted to the connection part 33 connected to the adjacent LED-mounted part 23. To connect the surfaces of the LED-mounted parts on the adjacent LED boards without a gap, the connection parts in the LED board are displaced to the back of the video display surface by about the thickness of the LED board. To displace the connection part 33 in the LED board, a slit is formed on the LED-mounted part 23 to extend one side of the connection part 33 at a boundary edge between the connection part 33 and the LED-mounted part 21 on the LED board. This slit allows bending the component mount 23 on the LED board to displace the connection part 22 in the LED board to the back of the video display surface by about the thickness of the LED board, thus connecting the LED-mounted part 23 on the LED board to the LED-mounted part 21 on the adjacent LED board without a gap.

Although a slit is described in the example in FIG. 14, simply bending a portion around a boundary edge between the connection part 33 and the LED-mounted part 23 on the LED board can also displace the connection part 33 in the LED board to the back of the video display surface by about the thickness of the LED board, thus connecting the LED-mounted part 23 on the LED board to the LED-mounted part 21 on the adjacent LED board without a gap.

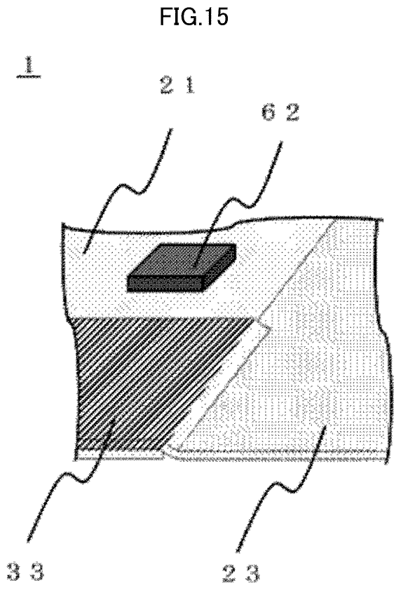

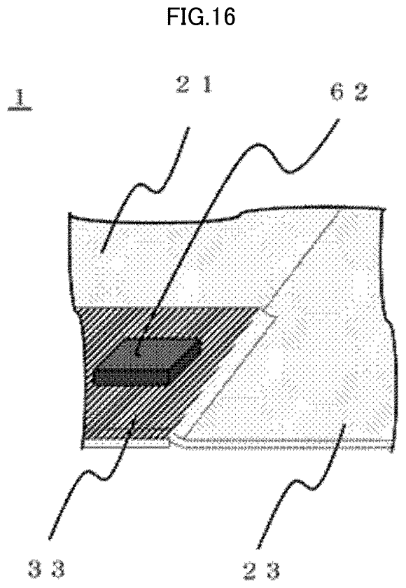

FIGS. 15 and 16 each are a partial cross-sectional view of an LED board included in the video display device according to Embodiment 2, illustrating the back of the video display surface of the LED board. As illustrated in FIG. 15, the connection part 33 in the LED board is fitted to the back of the video display surface of the LED-mounted part 21 on the LED board 11 on the back of the video display surface of the LED board included in the surface emitter. An LED control component 71 is mounted on the LED-mounted part 21 on the back of the video display surface of the LED board. As illustrated in FIG. 16, a component mount 62 on which an LED control component is mountable may be mounted on the connection part 33 on the back of the video display surface of the LED board included in the surface emitter.

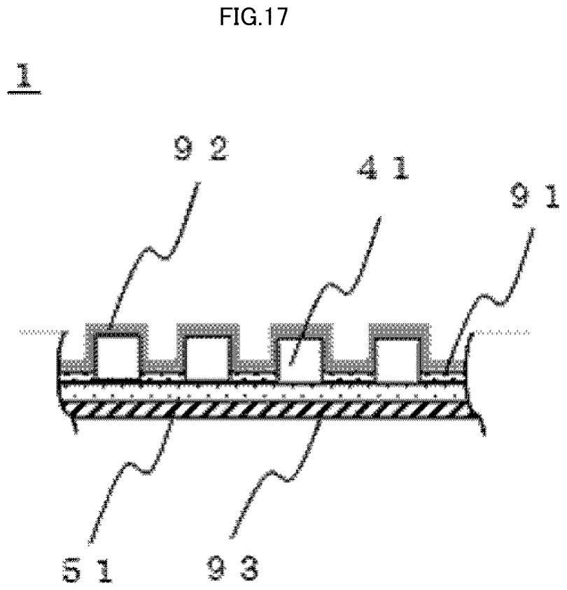

FIG. 17 is a schematic cross-sectional view of the surface emitter in the video display device according to Embodiment 4, with the video display surface of the surface emitter coated with resin. As illustrated in FIG. 17, the LEDs 41 are mounted on the circuit board 51 in the LED board. The surface of the circuit board 51 is typically covered with a cover lay film 91 to protect the circuit board 51. The surface of the surface emitter, or more specifically, the LEDs 41 and the cover lay film 91 may be coated with a resin film 92. Coating with the resin film 92 can provide waterproofness. The resin film 92 may have properties such as weather resistance or ultraviolet absorption properties to improve the weather resistance of the surface emitter. Resin used in this case is to include transparency in addition to the weather resistance or ultraviolet absorption properties. Examples of such resin include, but are not limited to, a single resin film such as an acrylic film, a cycloolefin film, or an olefine film, and a multi-layer film formed by laminating films with different functions. The resin may be film- or sheet-shaped. Such a resin film or sheet may be bonded to the surface emitter by, but not limited to, vacuum lamination, vacuum air-pressure forming, or a three-dimension overlay method (TOM). The resin film or sheet may be bonded to the surface emitter with a gluing agent or an adhesive.

Of the surface of the surface emitter, the portions including the LED-mounted parts alone in the LED board included in the surface emitter may be covered with the resin film 92. Of the surface of the LED board, the portions including the LEDs may be left uncovered with the resin film 92, whereas the other portions may be coated with resin. In another example, the LEDs alone may be covered with a resin film or sheet to expose only the LEDs.

As illustrated in FIG. 17, to increase the strength of the surface emitter, a reinforcement 93 may be located on the back of the video display surface. Examples of the reinforcement include, but are not limited to, a metal sheet, a resin sheet, a fiber reinforced plastic (FRP) sheet, a carbon fiber reinforced plastic (CFRP) sheet, and a rubber sheet. To reduce the unevenness of the video display surface of the surface emitter, such a reinforcement may have recesses or holes matching the shapes of the LED control components.

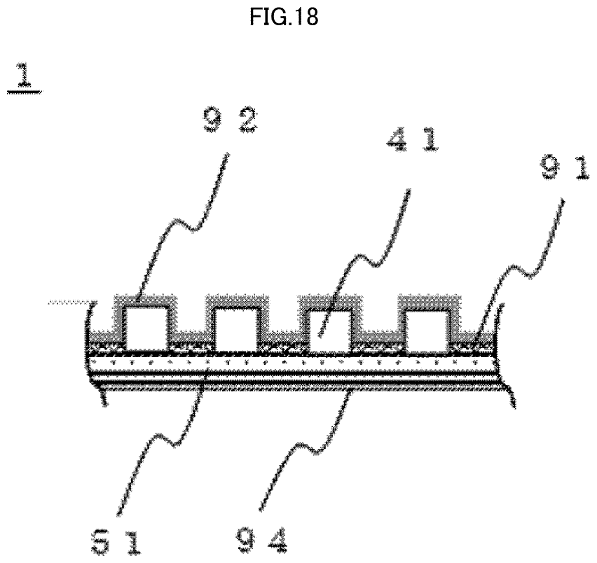

FIG. 18 is a schematic cross-sectional view of the surface emitter in the video display device according to Embodiment 4, with a light shield located on the back of the video display surface of the surface emitter. As illustrated in FIG. 18, a light shield 94 may be located on the back of the video display surface of the surface emitter. The light shield 94 blocks light from the back surface and improves the viewability of images displayed on the video device.

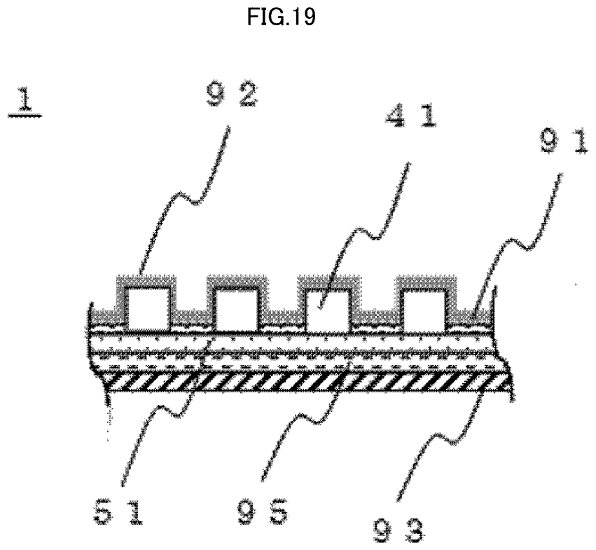

FIG. 19 is a schematic cross-sectional view of the surface emitter in the video display device according to Embodiment 4, with the connection parts bonded to the LED-mounted parts on the LED boards included in the surface emitter with an adhesive 95. As illustrated in FIG. 19, a portion in which the LED-mounted part on an LED board and the connection part in the adjacent LED board overlap each other may be bonded for strength. Examples of a bonding method include, but are not limited to, fastening the back of the video display surface of the component mount to the video display surface side of the connection part with an adhesive, a snap fastener, or a gluing agent.

Such elongated LED boards according to the embodiment of the present disclosure are connected together to have a surface emitter, with the mounts and the connection parts in adjacent LED boards overlapping and fitted to each other. The surface emitter used as a video display device is easily upsized.

### Embodiment 5

The surface emitter including the LED boards according to Embodiment 1 has been described above. A surface emitter including the LED boards according to Embodiment 2 is now described. Each set of adjacent LED boards has the mounts and the connection parts overlapping and fitted to each other into the surface emitter.

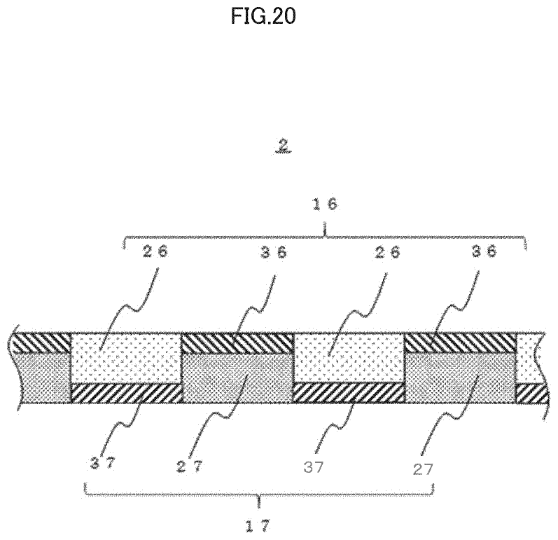

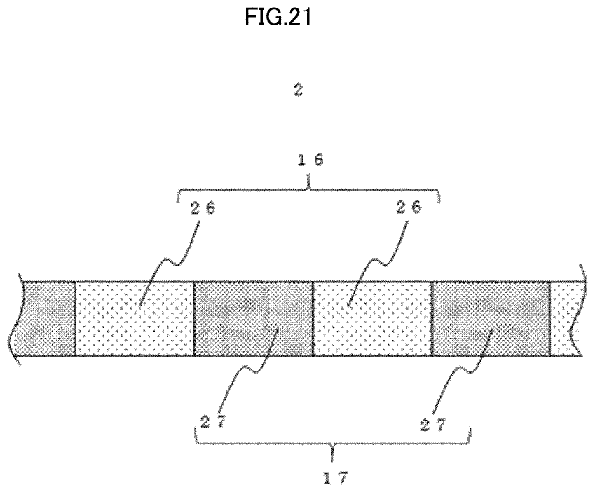

FIG. 20 is a schematic plan view of a surface emitter in a video display device according to Embodiment 5, illustrating the back of a video display surface of the surface emitter. On the back of the video display surface of a surface emitter 2, connection parts 37 in an LED board 17 are located on the back of the video display surface on which LEDs in the LED-mounted parts 26 on an LED board 16 are mounted, and connection parts 36 in the LED board 16 are located on the back of the video display surface on which LEDs in the LED-mounted parts 37 on the LED board 17 are mounted. FIG. 21 is a schematic plan view of the surface emitter in the video display device according to Embodiment 2, illustrating the video display surface of the surface emitter. The surface emitter 2 includes the LED-mounted parts 26 on the flexible LED board 16 and LED-mounted parts 27 on the flexible LED board 17 alternately and regularly arranged. The surface emitter according to the embodiment includes a combination of two LED boards. The connection parts of one of the LED boards and the connection parts of the other LED board are fitted together without overlapping each other.

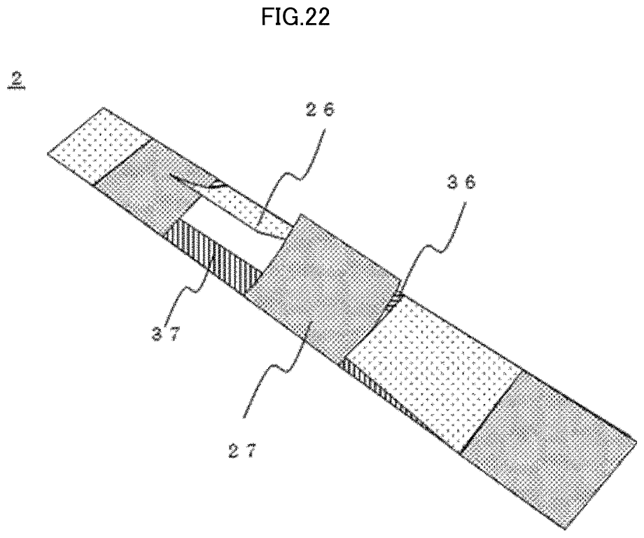

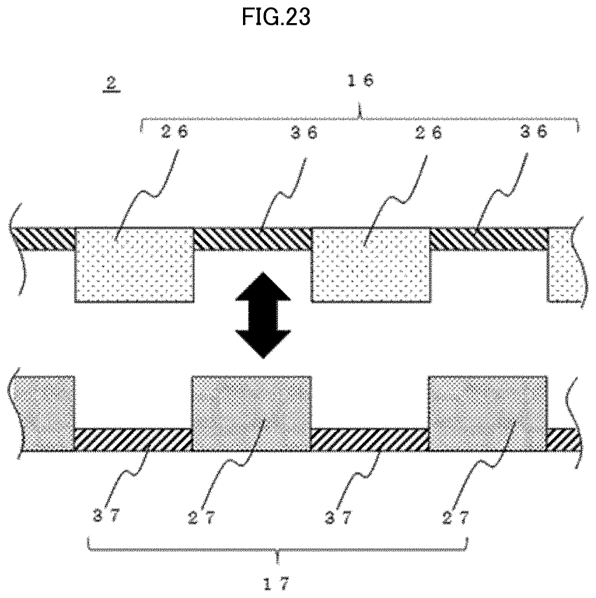

FIG. 22 is a perspective view of the surface emitter in the video display device according to Embodiment 5, illustrating the video display surface. In FIG. 23, the mounts 27 on the LED board 16 and the connection parts 37 in the LED board 17 overlap and are fitted to each other. The mounts 27 on the LED board 17 and the connection parts 36 in the LED board 16 are fitted together. Thus, the LED boards overlap and are fitted to each other into the surface emitter 2, with the sides on the back of the LED-mounted parts on the LED board placed on the connection parts in the facing LED board. Such elongated LED boards according to the embodiment of the present disclosure overlap and are connected together to have a surface emitter. The surface emitter used as a video display device is easily upsized. In particular, the surface emitter includes LED boards alternately and periodically arranged to have the side of each LED-mounted part and the side of each connection part aligned on a single straight line. Such a surface emitter is conveniently installable at, particularly, a place elongated in the array direction.

FIG. 23 is a schematic plan view of two LED boards included in the surface emitter in the video display device according to Embodiment 5. As illustrated in FIG. 23, the surface emitter 2 includes LED boards alternately and periodically arranged to have the side of each LED-mounted part and the side of each connection part aligned on a single straight line. The surface emitter 2 includes the LED boards 16 and 17 overlapping each other. The LED board 16 includes multiple LED-mounted parts 26 on which LEDs are mounted and the connection parts 36 each connecting adjacent LED-mounted parts 26 of the multiple LED-mounted parts 26 to each other. In the LED board 16, the LED-mounted parts 26 and the connection parts 36 are alternately arranged to have one side of each LED-mounted part 26 and one side of each connection part 36 aligned on a single straight line. The sides of the alternately arranged LED-mounted parts 26 and connection parts 36 aligned on a straight line have substantially the same length.

In the manner as in the LED board 16, the LED board 17 includes the multiple LED-mounted parts 27 on which LEDs are mounted and the connection parts 37 each connecting adjacent LED-mounted parts 27 of the multiple LED-mounted parts 27 to each other. In the LED board 17, the LED-mounted parts 27 and the connection parts 37 are alternately arranged to have one side of each LED-mounted part 27 and one side of each connection part 37 aligned on a single straight line. The sides of the alternately arranged LED-mounted parts 27 and connection parts 37 aligned on a straight line have substantially the same length.

Each LED-mounted part on either one of the LED board 16 or 17 overlaps the corresponding connection part in the other one of the LED board 16 or 17. More specifically, two LED boards are combined, and the connection part in one LED board and the connection part in the other LED board are fitted together without overlapping each other. The connection parts 37 in the LED board 17 are placed on the back of the video display surface of the LED-mounted parts 26 on the LED board 16. The connection parts 37 in the LED board 17 are placed on the back of the video display surface of the LED-mounted parts 26 on the LED board 16. The LED boards 16 and 17 overlap and are fitted to each other into the surface emitter 2. The LED boards 16 and 17 overlap and are fitted to each other with the LED-mounted parts 26 on the LED board 16 and the LED-mounted parts 27 on the LED board 17 alternately arranged to be an elongated video display device.

The LED-mounted parts 26 and the connection parts 36 in the LED board 16 and the LED-mounted parts 27 and the connection parts 37 in the LED board 17 are arrayed in a longitudinal direction, and the direction perpendicular to the longitudinal direction is a vertical direction. The dimension in the vertical direction of the connection parts 36 in the LED board 16 and the connection parts 37 in the LED board 17 is equal to or smaller than a half of the dimension in the vertical direction of the LED-mounted parts 26 on the LED board 16 and the LED-mounted parts 27 on the LED board 17 to have the LED boards 16 and 17 overlapping and fitted to each other.

To reduce unevenness on the video display surface of the surface emitter 2, LED control components mounted on the back of the video display surface of the LED-mounted parts 26 on the LED board 16 and the back of the video display surface of the LED-mounted parts 27 on the LED board 17 are preferably mounted in areas, of the back of the video display surface of the LED-mounted parts 26 on the LED board 16 and the back of the video display surface of the LED-mounted parts 27 on the LED board 17, in which neither the connection parts 37 in the LED board 17 nor the connection parts 36 in the LED board 16 are mounted.

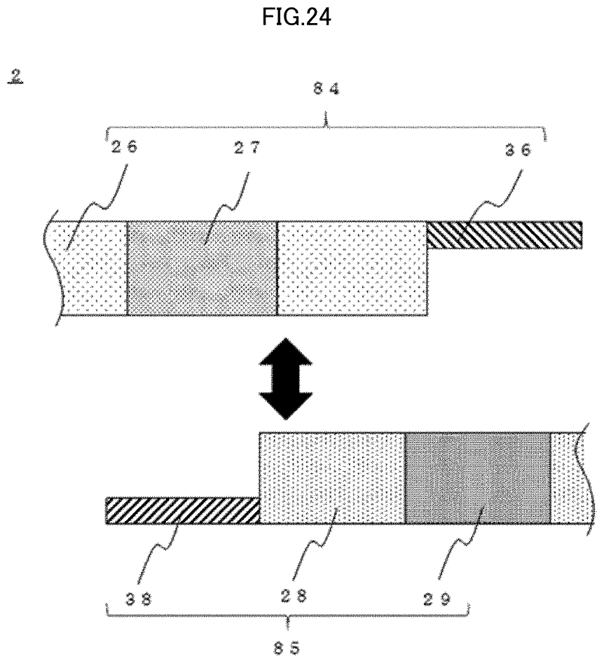

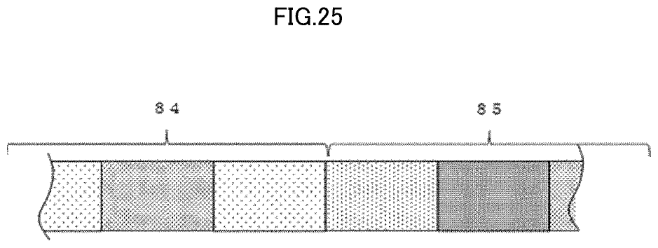

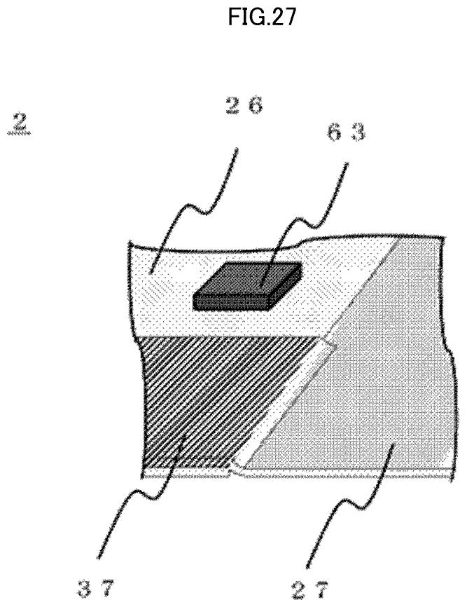

FIG. 24 is a schematic plan view of two fitted LED boards each including the LED boards that overlap and are fitted to each other, the two fitted LED boards being included in the surface emitter in the video display device according to Embodiment 5. FIG. 25 is a schematic plan view of the surface emitter including two fitted LED boards each including the LED boards according to Embodiment 2 overlapping and fitted to each other. As illustrated in FIG. 25, a first fitted LED board 84 includes multiple LED boards overlapping and fitted together in the array direction. A second fitted LED board 85 similarly includes multiple LED boards overlapping and fitted together in the array direction. The first fitted LED board 84 and the second fitted LED board 85 overlap and are fitted to each other in the array direction included in the surface emitter 2 upsized in the array direction. As illustrated in FIG. 24, the surface emitter illustrated in FIG. 25 includes the connection part 36 protruding at one end of the first fitted LED board 84 and a connection part 38 protruding at one end of the second fitted LED board 85 to face the first fitted LED board 84. The connection part 38 in the second fitted LED board 85 is placed on the back of the LED-mounted part 27 on the first fitted LED board 84, and the connection part 36 in the first fitted LED board 84 is placed on the back of an LED-mounted part 29 on the second fitted LED board 85. Thus, the first and second fitted LED boards 84 and 85 overlap and are fitted to each other into the surface emitter 2 upsized in the array direction illustrated in FIG. 27. Other than the manner of fitting, the surface emitter has the same structure as the surface emitter including the LED boards including the connection parts periodically arranged near the middle portion of the LED-mounted parts, with the mounts and the connection parts in adjacent LED boards overlapping and fitted to each other, and is not described.

A larger video display device has a greater overall weight. A large screen with multiple units of fitted LED printed circuit boards as above satisfies both the portability and the installability. The video display device according to embodiments of the present disclosure is flexible, and thus can be folded, rolled, or stored into a compact container for transportation. Dividing a video display device into multiple units of fitted LED printed circuit boards can downsize the storage space and improve the portability.

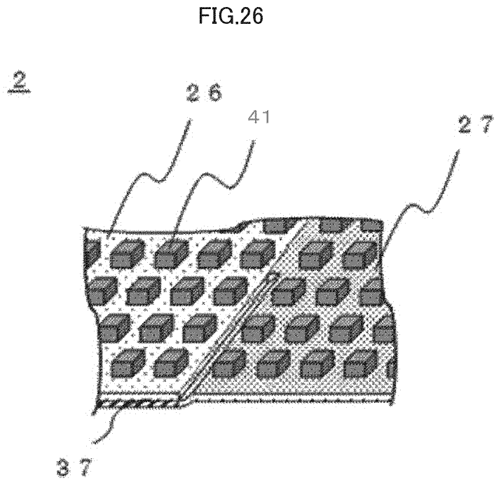

FIG. 26 is a partial cross-sectional view of the LED boards included in the surface emitter in the video display device according to Embodiment 5, illustrating the video display surfaces of the LED boards. As illustrated in FIG. 26, the surface emitter 2 according to the present embodiment includes the LED board 16 including the LED-mounted parts 26 on which multiple LEDs 51 are mounted and the LED board 17 including the LED-mounted parts 27 on which multiple LEDs 51 are mounted. The LED-mounted parts 26 and the LED-mounted parts 27 are alternately and regularly arranged in the longitudinal direction. To connect the surfaces of the LED-mounted part 26 on the LED board 16 and the LED-mounted part 27 on the LED board 17 without a gap, the connection part 37 in the LED board 17 is displaced to the back of the video display surface by about the thickness of the LED board 16. To displace the connection part 37 in the LED board 17, a slit is formed on a side closer to the LED-mounted part 27 at a boundary edge between the connection part 37 and the LED-mounted part 27 on the LED board 17. This slit allows bending the LED-mounted part 27 on the LED board 17 to displace the connection part 37 in the LED board 17 to the back of the video display surface by about the thickness of the LED board 16, thus connecting the LED-mounted part 27 on the LED board 17 to the LED-mounted part 26 on the adjacent LED board 16 without a gap. Although the surface emitter according to Embodiment 5 has a slit, simply bending a portion of the LED-mounted part 27 on the LED board 17 around a boundary edge between the connection part 37 and the LED-mounted part 27 can also displace the connection part 37 in the LED board 17 to the back of the video display surface by about the thickness of the LED board 16.

FIG. 27 is a partial cross-sectional view of the LED boards included in the surface emitter in the video display device according to Embodiment 5, illustrating the back of the video display surfaces of the LED boards. As illustrated in FIG. 27, on the back of the surface emitter 2 according to Embodiment 2, the connection part 37 in the LED board 17 is located on the back of the video display surface of the LED-mounted part 26 on the LED board 16. An LED control component 72 is mounted on the LED-mounted part 26 on the back of the video display surface of the LED board 16. The connection part 37 in the LED board 17 is located on the back of the video display surface of the LED-mounted part 26 on the LED board 16. The connection part 36 in the LED board 16 is located on the back of the video display surface of the LED-mounted part 27 on the LED board 17. Although a component mount 63 on which an LED control component is mountable is mounted on the LED-mounted part 26 in FIG. 27, an LED control component may be mounted on the connection part 37.

Such elongated LED boards according to the embodiment of the present disclosure are connected together to have a surface emitter, with the mounts and the connection parts in adjacent LED boards overlapping and fitted to each other. The surface emitter used as a video display device is easily upsized. The video display device including the surface emitters including the LED boards is conveniently installable at, particularly, a place elongated in the array direction of the LED board.

### Embodiment 6

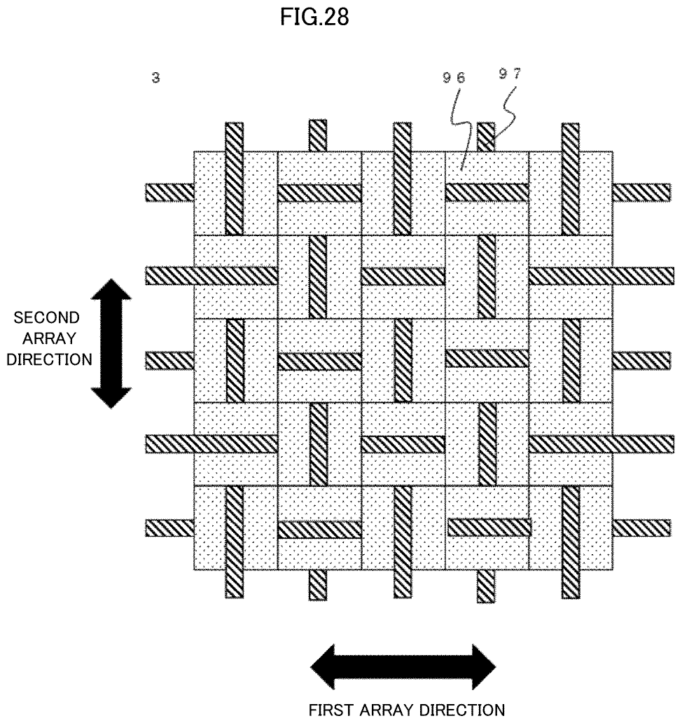

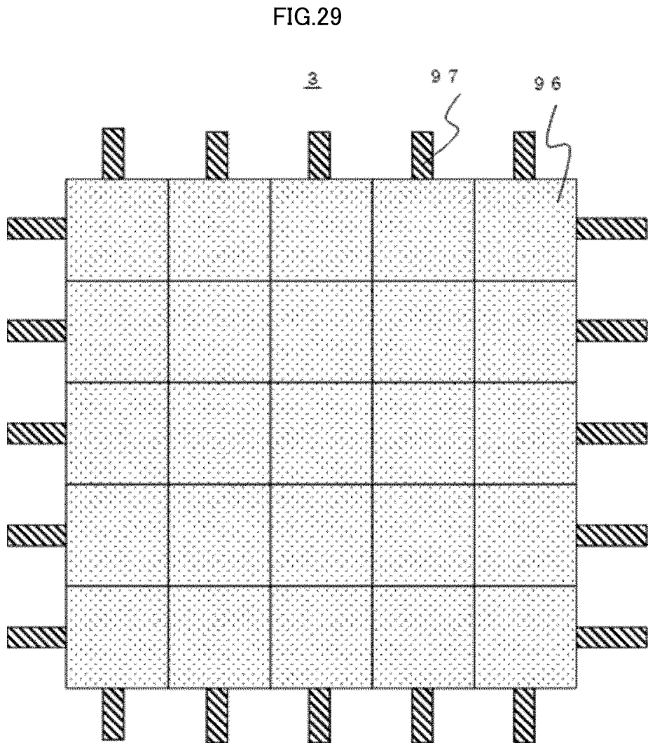

The surface emitters each including the LED boards according to one of Embodiments 1 and 2 have been described above. A surface emitter including the LED boards according to Embodiment 3 is now described. Each set of adjacent LED boards has the mounts and the connection parts overlapping and fitted to each other into the surface emitter. FIG. 28 is a schematic plan view of a surface emitter in a video display device according to Embodiment 6, illustrating the back of a video display surface of the surface emitter. FIG. 29 is a schematic plan view of the surface emitter in the video display device illustrating the video display surface. In the back view of the video display surface of a surface emitter 3, connection parts 97 in LED boards 18 arrayed in a second array direction are located on the back of the video display surface of LED-mounted parts 96 on the LED boards 18 arrayed in a first array direction. The connection parts 97 in the LED boards 18 arrayed in the first array direction are located on the back of the video display surface of the LED-mounted parts 96 on the LED boards 18 arrayed in the vertical direction. The LED boards 18 arrayed in the first and second array directions overlap and are fitted together.

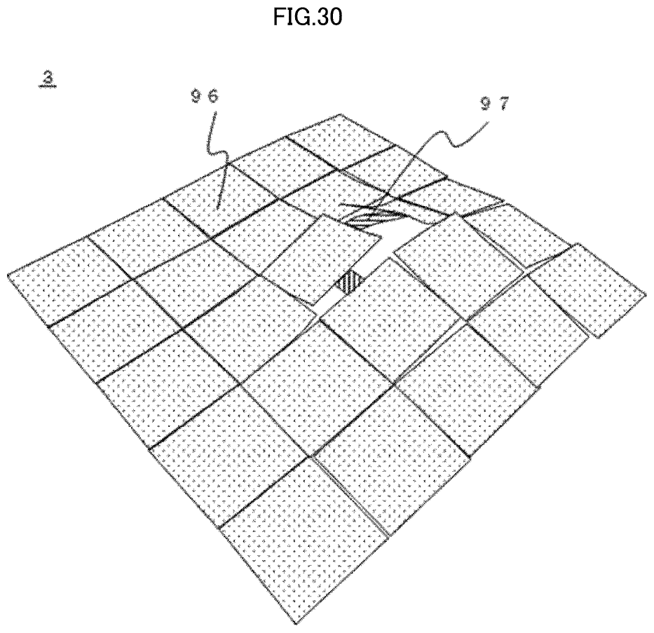

FIG. 30 is a perspective view of the surface emitter in the video display device according to Embodiment 6, illustrating the video display surface of the surface emitter. In FIG. 30, the connection parts 97 in the LED boards 18 arrayed in the second array direction are located on the back of the video display surface of the LED-mounted parts 96 on the LED boards 18 arrayed in the first array direction. The connection parts 97 in the LED boards 18 arrayed in the first array direction are located on the back of the video display surface of the LED-mounted parts 96 on the LED boards 18 arrayed in the second array direction. The LED boards 18 arrayed in the first and second array directions overlap and are fitted together.

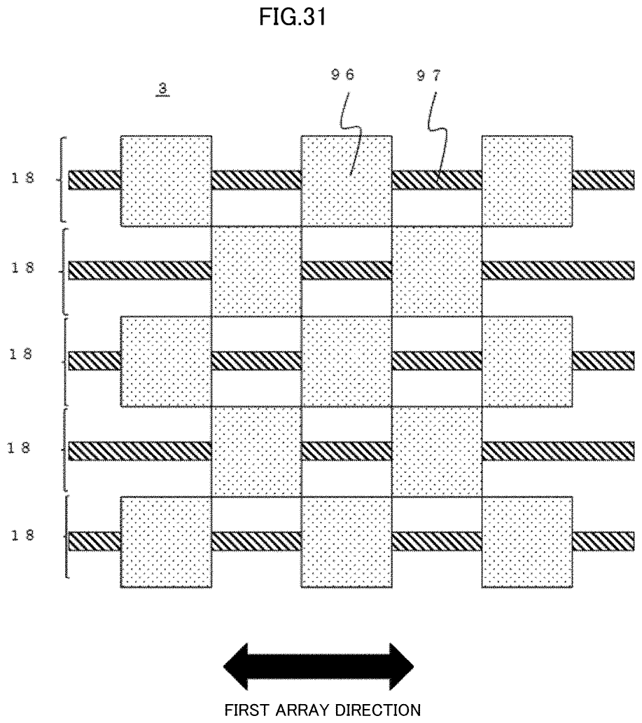

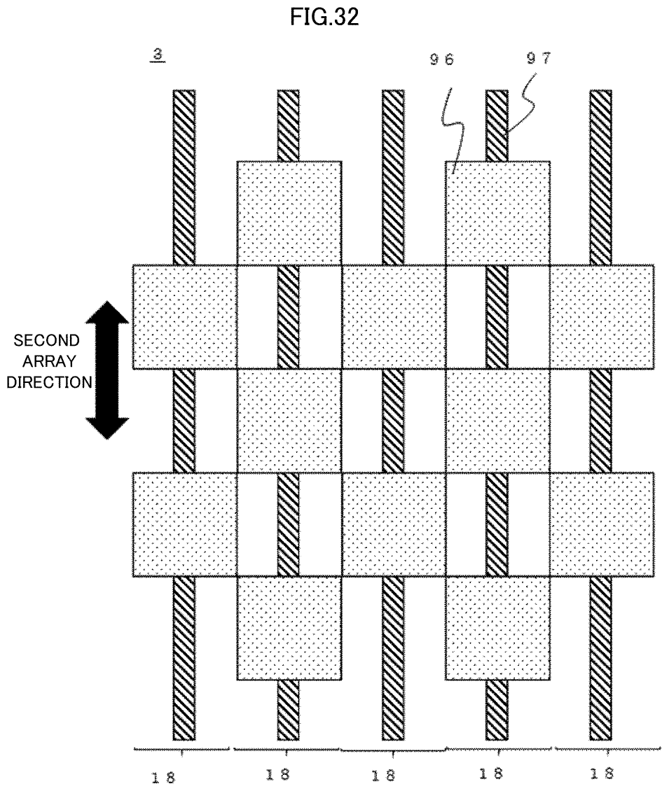

FIG. 31 shows the LED boards arrayed in the first array direction included in the video display device according to Embodiment 6. FIG. 32 shows the LED boards arrayed in the second array direction included in the video display device according to Embodiment 6. As illustrated in FIG. 31, the multiple LED boards 18 each include the LED-mounted parts 96 on which LEDs are mounted and the connection parts 97 each connecting adjacent LED-mounted parts of the LED-mounted parts 96. The LED boards 18 are staggered in the first array direction. As illustrated in FIG. 32, the multiple LED boards 18 each include the LED-mounted parts 96 on which LEDs are mounted and the connection parts 97 each connecting adjacent LED-mounted parts of the LED-mounted parts 96. The LED boards 18 are staggered in the second array direction. The LED boards arrayed in the first array direction as illustrated in FIG. 31 and the LED boards arrayed in the second array direction as illustrated in FIG. 32 are fitted together in a knitted manner to place the LED-mounted parts 96 on the front surface and the connection parts 97 on the back, thus providing the surface emitter 3. In other words, the video display surfaces of the LED-mounted parts 96 on the LED boards 18 arrayed in the second array direction are located on the connection parts 97 in the LED boards 18 arrayed in the first array direction. The video display surfaces of the LED-mounted parts 96 on the LED boards 18 arrayed in the first array direction are located on the connection parts 97 in the LED boards 18 arrayed in the second array direction. The LED boards 18 arrayed in the first and second array directions overlap and are fitted together. Other than the manner of fitting, the surface emitter has the same structure as the surface emitter described above, and is not described. Such elongated LED boards according to the embodiment of the present disclosure are fitted together into a surface emitter. The surface emitter used as a video display device is easily upsized. In particular, the surface emitter including the square LED-mounted parts has higher strength with the multiple LED boards overlapping and fitted together in a knitted manner.

### Embodiment 7

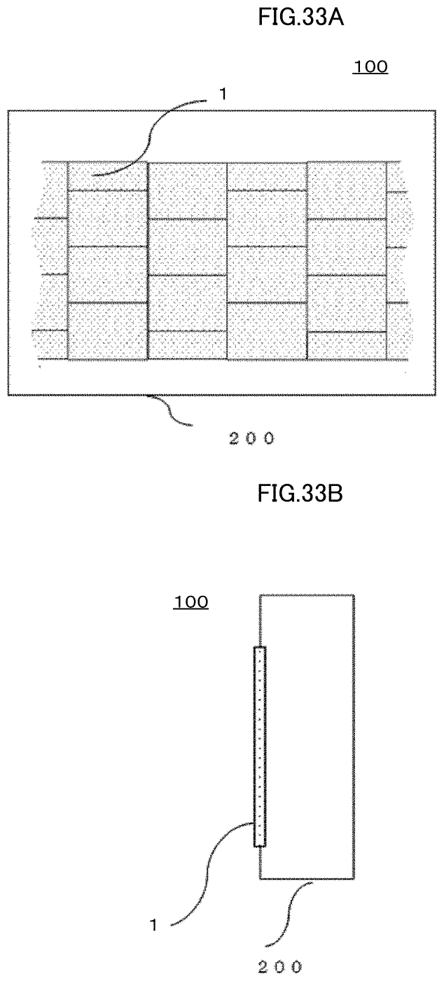

A video display device including the surface emitters according to any of Embodiments 4 to 6 is described. FIGS. 33A and 33B are plan and side views of a video display device according to Embodiment 7. FIG. 33A is a plan view of a video display device 100 according to Embodiment 7. FIG. 33B is a side view of the video display device 100 according to Embodiment 7. The surface emitters according to any of Embodiments 4 to 6 each include LED boards. Each LED board includes multiple LED-mounted parts each including multiple LEDs mounted on a flexible printed circuit and connection parts being portions of the flexible printed circuit and each connecting adjacent LED-mounted parts of the multiple LED-mounted parts. The adjacent LED boards have the mounts and the connection parts overlapping and fitted to each other into the surface emitter. Although a larger video display device may not include a housing to which the surface emitters are fastened, the video display device 100 may include a housing formed from an elastic material such as resin or carbon fiber reinforced plastics. FIGS. 33A and 33B show the video display device 100 including a housing. The video display device 100 in FIGS. 33A and 33B includes a housing 200 and surface emitters 1.

The housing 200 may have any shape, and is formed from an elastic material such as resin or carbon fiber reinforced plastics. The housing 200 protects the surface emitters 1 in the housing 200 from water, dust, and external force.

The housing 200 has an opening in one surface. The opening receives the surface emitters 1 arranged in a matrix in the vertical and longitudinal directions. The video display device 100 includes a display screen on which the surface emitters 1 are located. The video display device 100 may include a display screen of any size.

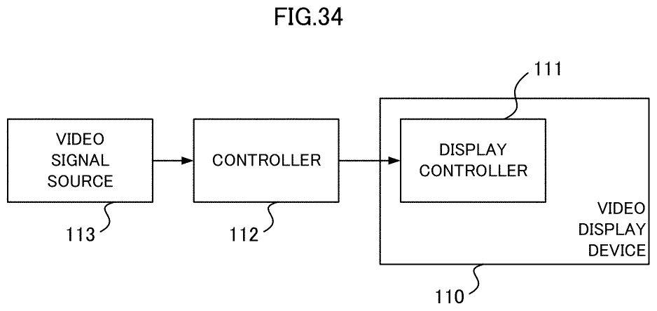

FIG. 34 is a structural diagram of the video display device according to Embodiment 7, illustrating a use example of the video display device. As illustrated in FIG. 34, the video display device 100 includes a display controller 111 being an electric circuit located on the circuit board 51. The display controller 111 controls power supplied to the LEDs 41 from a power source, which is not illustrated, to adjust the luminance of the LEDs 41, thereby adjusting the luminance and color development on the surface emitters 1 including the LEDs 41. Thus, the display controller 111 controls the display of videos on the video display device 100.

As illustrated in FIG. 34, the video display device 100 is connected to a video signal source 113 through a controller 112. The video signal source 113 is, for example, a server that outputs prestored video signals to the controller 112. The controller 112 is a computer that converts the video signals input from the video signal source 113 in accordance with the array of the LEDs 41 in each surface emitter 1 in the video display device 100, determines the luminance and color development on the surface emitter 1, and outputs the resultants to the display controller 111.

Thus, the video display device 100 separately adjusts the luminance and color development of the individual LEDs 41 in each of the surface emitters 1 arrayed in a matrix to display images. The video display device 100 then changes the images with time to display video images (videos). The elongated LED boards according to the embodiment of the present disclosure overlap and are connected together to have a surface emitter. The surface emitter used as a video display device is easily upsized.

### REFERENCE SIGNS LIST

1, 2, 3 Surface emitter
11, 12, 13, 14, 15, 16, 17, 18 LED board
21, 22, 23, 24, 25, 26, 27, 28, 29, 96 LED-mounted part
31, 32, 33, 34, 36, 37, 38, 97 Connection part
41, 51 LED
51 Circuit board
61, 62, 63 Component mount
81, 84 First fitted LED board
82, 85 Second fitted LED board
83 Fitted LED board
91 Cover lay film
92 Resin film
93 Reinforcement
94 Light shield
95 Adhesive
100 Video display device
111 Display controller
112 Controller
113 Video signal source
200 Housing

1. An LED board, comprising:
a circuit board being flexible; and
a plurality of LED-mounted parts arrayed on the circuit board at regular intervals in a constant direction, each of the plurality of LED-mounted parts including a plurality of LEDs being light-emitting diodes,
wherein
the circuit board includes LED portions including the plurality of LED-mounted parts and non-LED portions including no LED-mounted parts, the LED portions and the non-LED portions are arrayed alternately, and
the plurality of LED-mounted parts each have, in an array direction in which the plurality of LED-mounted parts are arrayed, a dimension equal to an interval between adjacent LED-mounted parts of the arrayed plurality of LED-mounted parts.

2. The LED board according to claim 1, wherein
each of the arrayed plurality of LED-mounted parts has, in a middle portion of a side of the LED-mounted part perpendicular to the array direction, a boundary with a corresponding non-LED portion of the circuit board.

3. The LED board according to claim 1, wherein
each of the plurality of LED-mounted parts has an edge including a side, the side being parallel to the array direction overlapping an edge of a corresponding LED portion of the circuit board.

4. The LED board according to claim 1, wherein
each of the plurality of LED-mounted parts has a square profile as viewed in plan.

5.-8. (canceled)

9. The LED board according to claim 2, wherein
each of the plurality of LED-mounted parts has a square profile as viewed in plan.

10. A surface emitter, comprising:
a plurality of the LED boards according to claim 1 arranged in a direction perpendicular to the array direction of the plurality of LED-mounted parts,
wherein the plurality of LED boards are fitted together, with the plurality of LED-mounted parts on each of the plurality of LED boards overlapping the non-LED portions of an adjacent LED board of the plurality of LED boards.

11. A surface emitter, comprising:
a plurality of the LED boards according to claim 1,
wherein the plurality of LED boards are fitted together, with each non-LED portion of the circuit board on each of the plurality of LED boards receiving the plurality of LED-mounted parts on each of adjacent LED boards of the plurality of LED boards in an overlapping manner.

12. A surface emitter, comprising:
a plurality of the LED boards according to claim 2,
wherein the plurality of LED boards are fitted together, with each non-LED portion of the circuit board on each of the plurality of LED boards receiving the plurality of LED-mounted parts on each of adjacent LED boards of the plurality of LED boards in an overlapping manner.

13. A surface emitter, comprising:
two of the LED boards according to claim 3 combined together,
wherein the two LED boards are fitted to each other without the non-LED portions of the circuit board in one of the two LED boards overlapping the non-LED portions of the circuit board in another of the two LED boards.

14. A video display device, comprising:
the surface emitter according to claim 10; and
a housing having an opening to which the surface emitter is fitted.

15. A video display device, comprising:
the surface emitter according to claim 11; and
a housing having an opening to which the surface emitter is fitted.

16. A video display device, comprising:
the surface emitter according to claim 12; and
a housing having an opening to which the surface emitter is fitted.

17. A video display device, comprising:
the surface emitter according to claim 13; and
a housing having an opening to which the surface emitter is fitted.
